(19) United States
(12) Patent Application Publication
(10) Pub. No.: US 2025/0378215 A1
(43) Pub. Date: Dec. 11, 2025

(54) METHOD FOR SIMULATING AND ANALYZING WATER INRUSH CATASTROPHE IN TUNNEL CONSTRUCTION BASED ON PERIDYNAMICS AND TECHNIQUES FOR OPTIMIZING TUNNEL CONSTRUCTION

(71) Applicant: SHANDONG UNIVERSITY, Jinan (CN)

(72) Inventors: Shucai LI, Jinan (CN); Liping LI, Jinan (CN); Zongqing ZHOU, Jinan (CN); Chenglu GAO, Jinan (CN); Zhiwei YANG, Jinan (CN); Daosheng ZHANG, Jinan (CN); Zhuohui LI, Jinan (CN); Meixia WANG, Jinan (CN); Huaqing MA, Jinan (CN)

(73) Assignee: SHANDONG UNIVERSITY, Jinan (CN)

(21) Appl. No.: 19/307,079

(22) Filed: Aug. 22, 2025

Related U.S. Application Data
(63) Continuation-in-part of application No. 17/630,422, filed on Jan. 26, 2022.

(30) Foreign Application Priority Data
Feb. 25, 2020 (CN) 202010115622.4

(51) Int. Cl. G06F 30/13

(52) U.S. Cl. CPC G06F 30/13

(57) ABSTRACT

A design method for preventing and controlling water inrush catastrophe in tunnels and techniques for optimizing actual tunnel construction, specifically: discretizing calculation model into material points, setting virtual boundary layers outside boundary of calculation model; selecting size of horizon of material points to form neighborhood matrix of material points; making crustal stress equivalent to stress boundary condition, making karst cave water pressure equivalent to normal pressure, and converting displacement constraint and tunnel support into displacement boundary conditions; solving speed and displacement of material point, determining whether bonds of all material points meet failure condition, recording local damage situations; after initial balance calculation is stable, simulating tunnel construction process by using material point dormancy method; and according to physical values of optimization parameters of actual tunnel construction obtained by simulation results that meet the requirements of water inrush catastrophe prevention and control, implementing the optimized actual tunnel construction.

### CROSS-REFERENCES TO RELATED APPLICATIONS

The present invention is a continuation-in-part of U.S. application Ser. No. 17/630,422, filed on Jan. 26, 2022, which claims priority to International Application number PCT/CN2020/122920, entitled “PERIDYNAMICS METHOD AND SYSTEM FOR SIMULATING SUDDEN INRUSH WATER DISASTER OF TUNNEL ROCK MASS FAILURE”, as filed on Oct. 22, 2020, which claims priority to Chinese Application number 202010115622.4, as filed on Feb. 25, 2020. The entirety of each of the above-mentioned patent applications is hereby incorporated by reference herein and made a part of this specification.

### TECHNICAL FIELD

The present invention relates to the field of tunnels and underground engineering, in particular to a method for simulating and analyzing water inrush catastrophe in tunnel construction based on peridynamics and techniques for optimizing tunnel construction.

### BACKGROUND

With the rapid development of Country's transportation infrastructure construction and the gradual implementation of the strategy for making a powerful country in transportation, more and more tunnels are built in high mountains and valleys and go through karst and other groundwater-rich areas. In the process of tunnel construction, due to the influence of karst and other adverse geological structures and high-pressure groundwater, a rock mass failure water inrush catastrophe takes place most easily, which brings severe challenges to engineering safety construction. As one of the important means of geotechnical engineering research, numerical simulation can be used to simulate an evolution process of the water inrush catastrophe to reveal its catastrophe evolution mechanism. On this basis, further simulation optimization is carried out to adjust the design/construction parameters of tunnel engineering, to obtain the optimized construction plan based on the parameters that minimizes the impact of the water inrush catastrophe, and the optimized construction plan is applied to the actual tunnel construction to ensure the reliability and safety of the process of the tunnel construction.

However, conventional methods based on a theoretical framework of continuum mechanics, such as a finite element method, are difficult in simulating discontinuous problems such as material fracture, while discontinuous methods, such as a discrete element method, encounter a bottleneck of computational efficiency in solving engineering scale problems.

Peridynamics is a multi-scale numerical calculation method based on the idea of nonlocal actions. It describes mechanical behaviors of matters by solving a spatial integral equation, which breaks through the limitations of the conventional continuum mechanics method in solving discontinuous problems, avoids the singularity of solving a differential equation at a crack tip, and has unique advantages in continuous-discontinuous mechanical simulation such as crack extension and material failure. As a new numerical calculation method, peridynamics has been widely used in the field of solid mechanics. However, at present, there are fewer studies on large-scale engineering calculation of underground projects such as tunnels, especially for large-deformation and discontinuous geological disasters such as water inrush during tunnel construction. The inventor found that existing methods are difficult in describing progressive failure characteristics of rock mass under the action of excavation unloading, and cannot reveal an evolution mechanism of a water inrush channel; moreover, it is unable to provide optimized design solutions for the prevention and control of the water inrush catastrophe in the tunnel construction.

### SUMMARY

For the defects in the prior art, an objective of the present invention is to provide a method for simulating and analyzing water inrush catastrophe in tunnel construction based on peridynamics and techniques for optimizing tunnel construction. A forming process of a rock mass failure water inrush channel and a surrounding rock damage and failure mechanism in a tunnel construction process can be effectively described by discretizing calculation model into a series of material points having material and physical mechanics information in space, making an acting force of groundwater on rock mass equivalent to a boundary force on the material points, and establishing a basic motion equation in an integral form based on the idea of nonlocal actions in combination with a material point dormancy method describing a tunnel excavation unloading action.

To achieve the foregoing objective, the present invention is implemented by the following technical solutions:
An embodiment of the present invention provides a peridynamics method for tunnel rock mass failure water inrush catastrophe simulation. A calculation model is discretized into a series of material points having material and physical mechanics information in space, a virtual boundary layer of a certain thickness is set on an outer side of a boundary of the calculation model as an object to which boundary conditions are applied, and the influence of a boundary effect on calculation results is weakened;
a proper size of a horizon of the material points is selected to form a neighborhood matrix of the material points; a crustal stress received by the calculation model is made equivalent to a stress boundary condition of the calculation model, a karst cave water pressure is made equivalent to a normal pressure of the calculation model, and a displacement constraint and tunnel support are converted into a displacement boundary condition; a speed and a displacement of the material point are iteratively solved by using an adaptive dynamic relaxation algorithm, whether bonds of all the material points meet a failure condition or not is determination, and local damage situations are recorded; and
in the iterative solving process, a rock mass compression failure process is truly simulated by adding a short-range repulsion item in a basic governing equation; and after initial balance calculation is stable, a tunnel construction process is simulated through a way of staged excavation and lag support by using a material point dormancy method, so that a forming process of a rock mass failure water inrush channel in the tunnel construction process is simulated.

An embodiment of the present invention further provides a system for tunnel rock mass failure water inrush catastrophe simulation, comprising:
a model discretizing module, configured to discretize a calculation model into material points in space, and set a virtual boundary layer on an outer side of a boundary of the calculation model as an object to which boundary conditions are applied; and select a size of a neighborhood of the material points to form a neighborhood matrix of the material points;
a parameter equivalent model, configured to make a crustal stress on the calculation model equivalent to a stress boundary condition of the calculation model, make a karst cave water pressure equivalent to a normal pressure of the calculation model, and convert a displacement constraint and tunnel support into a displacement boundary condition;
a solving and determination model, configured to solve a speed and a displacement of the material points, determine whether bonds of all the material points meet a failure condition, and record local damage situations; and
the calculation model, configured to perform balance calculation, and simulate a tunnel construction process by using a material point dormancy method after initial balance calculation is stable.

An embodiment of the present invention further provides an electronic device, comprising a memory, a processor and a computer program stored on the memory and capable of running on the processor, wherein the peridynamics method for tunnel rock mass failure water inrush catastrophe simulation is implemented when the program is executed by the processor.

An embodiment of the present invention further provides a computer readable storage medium, storing a computer program, wherein the peridynamics method for tunnel rock mass failure water inrush catastrophe simulation is implemented when the program is executed by a processor.

An embodiment of the present invention further provides a design method for preventing and controlling water inrush catastrophe in tunnels and techniques for optimizing an actual tunnel construction, comprising:
constructing a calculation model for simulating an actual tunnel construction based on design parameters of the actual tunnel construction, engineering geological parameters and hydrogeological parameters;
discretizing the calculation model into a series of material points having material and physical mechanics information in space, setting a virtual boundary layer of a certain thickness on an outer side of a boundary of the calculation model as an object to which boundary conditions are applied, to weaken the influence of a boundary effect on calculation results;
selecting a proper size of a horizon of the material points to form a neighborhood matrix of the material points;
making a crustal stress received by the calculation model equivalent to a stress boundary condition of the calculation model, making a karst cave water pressure equivalent to a normal pressure of the calculation model, and converting a displacement constraint and tunnel support into a displacement boundary condition;
iteratively solving a speed and a displacement of the material point by using an adaptive dynamic relaxation algorithm, determining whether bonds of all the material points meet a failure condition or not, and recording local damage situations;
in a process of the iterative solving, truly simulating a rock mass compression failure process by adding a short-range repulsion item in a basic governing equation;
after an initial balance calculation is stable, simulating a tunnel construction process through a way of staged excavation and lag support by using a material point dormancy method;
adjusting the design parameters of the actual tunnel construction, inputting the adjusted design parameters into the calculation model, and repeat the simulation of the tunnel construction process until a simulation result meets a requirement that there will be no more water inrush catastrophe during the tunnel construction process, or the probability and/or risk level of the water inrush catastrophe will be reduced to the lowest level in a predefined risk level list, obtaining physical values of the optimized design parameters for the actual tunnel construction; and
according to the obtained optimized design parameters for the actual tunnel construction, adjusting an excavation depth, excavation method, support strength, and support timing of tunnel to performing the actual tunnel construction, to ensure the reliability and safety of the actual tunnel construction.

The embodiments of the present invention have the following beneficial effects:
(1) In one or more implementations of the present invention, a crustal stress and a karst cave water pressure on the calculation model of underground projects such as tunnels are made equivalent to the stress boundary conditions, so that a quantity of the material points discretized from the calculation model is decreased, the calculation efficiency is improved, and the calculation precision is guaranteed.
(2) One or more implementations of the present invention provide an improved basic motion equation of the peridynamics, so that the one-way coupling action of groundwater (fluid) on rock mass (solid coupling) is simulated; and by introducing a short-range repulsion, a rock mass compression process is simulated, and a simulation effect closer to actual situations is achieved.
(3) In one or more implementations of the present invention, efficient solving of the peridynamics in a quasi-static problem is realized by using the adaptive dynamic relaxation method; and the tunnel construction process is simulated through the way of staged excavation and lag support by using the material point dormancy method, so that numerical simulation of the water inrush catastrophe evolution process in the excavation process of underground projects such as tunnels is realized.
(4) In one or more implementations of the present invention, there is provided an optimization design method for prevention and control of water inrush catastrophe during tunnel construction, realizing optimization of construction parameters based on numerical simulation results of peridynamics of water inrush disaster during tunnel construction, and providing key design parameters for prevention and control of water inrush disaster during tunnel construction.

### BRIEF DESCRIPTION OF THE DRAWINGS

The accompanying drawings constituting a part of the present invention are used to provide a further understanding of the present invention. The exemplary embodiments of the present invention and descriptions thereof are used to explain the present invention, and do not constitute an improper limitation of the present invention.

FIG. 1 is a flow chart of Embodiment 1 of the present invention.

FIG. 2 is a schematic diagram of a tunnel construction model of Embodiment 2 of the present invention.

FIG. 3A is a schematic diagram of simulation of a forming process of a water inrush channel of Embodiment 2 of the present invention.

FIG. 3B is another schematic diagram of simulation of a forming process of a water inrush channel of Embodiment 2 of the present invention.

FIG. 4A is a schematic diagram of simulation of surrounding rock damage features of Embodiment 2 of the present invention.

FIG. 4B is another schematic diagram of simulation of surrounding rock damage features of Embodiment 2 of the present invention.

FIG. 5 is a flowchart of an optimization design method for prevention and control of water inrush catastrophe during tunnel construction of Embodiment 6 of the present invention.

### DETAILED DESCRIPTION

It should be noted that, the following detailed descriptions are all exemplary, and are intended to provide further descriptions of the present invention. Unless otherwise specified, all technical and scientific terms used herein have the same meaning as commonly understood by a person of ordinary skill in the art to which the present invention belongs.

It should be noted that terms used herein are only for describing specific implementations and are not intended to limit exemplary implementations according to the present invention. As used herein, the singular form is also intended to include the plural form unless the context clearly dictates otherwise. In addition, it should further be understood that, terms “comprise” and/or “comprising” used in this specification indicate that there are features, steps, operations, devices, components, and/or combinations thereof.

### Embodiment 1

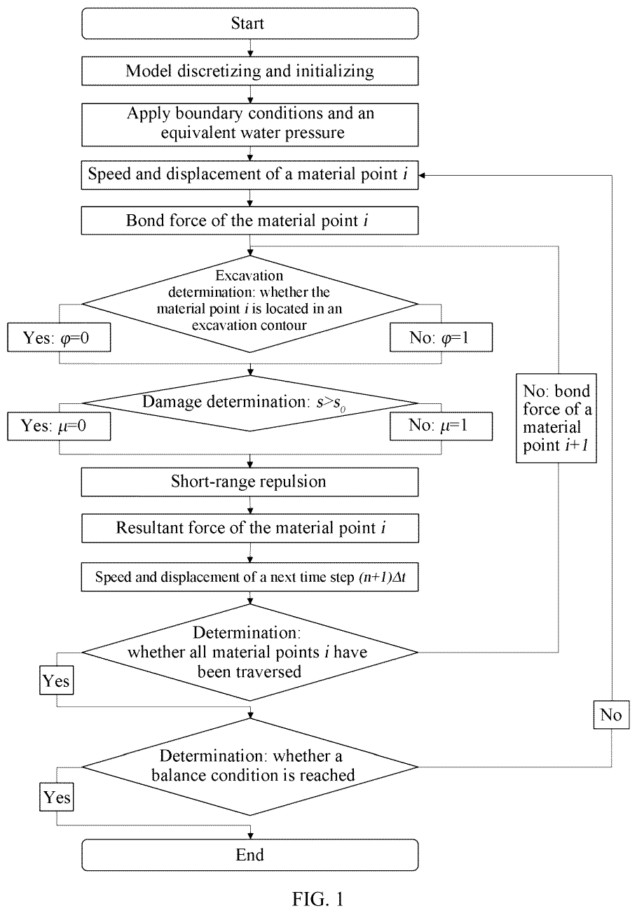

The present invention is described in detail below in combination with FIG. 1. Specifically, a structure is as follows:

The present embodiment provides a peridynamics method for tunnel rock mass failure water inrush catastrophe simulation, comprising the following steps:
(1) A calculation model is discretized into a series of material points having material and physical mechanics information in space, a virtual boundary layer of a certain thickness is set on an outer side of a boundary of the calculation model, the virtual boundary layer and the calculation model have a same discretizing way, and information such as coordinates, areas and volumes of the material points is stored in matrices respectively.

The virtual boundary layers are a correction method for weakening the influence of a boundary effect on the calculation model, thereby effectively transmitting external information such as a displacement and a stress into the calculation model and guaranteeing accuracy of simulation results. Applying information such as the stress, the displacement and constraints to the virtual boundary layer and then transmitting the information into the calculation model effectively guarantee the accuracy of the simulation results at boundaries of the calculation model.
(2) A proper size of a horizon of the material points is selected to form a neighborhood matrix of all the material points, and an interaction relation between the material points is determined. The interaction relation may be represented by the concept of bond.

The horizon of a certain material point means a range where the certain material point interacts with other material points:

$${H}_{x} = \{ {x}^{′} ∈ R : ‖ {x}^{′} - x ‖ \leq δ \} ;$$

wherein, R is a calculation region, x is any material point in the calculation region, x′ is any other material points within a certain space range of the material point x, if a distance between two points is not greater than a given constant δ, the two points have a certain interaction relation, and the range δ is the size of the horizon.
(3) A crustal stress on the calculation model is made equivalent to a stress boundary condition of the calculation model, a karst cave water pressure is made equivalent to a normal pressure of the calculation model, a displacement constraint and tunnel support are converted into a displacement boundary condition, and the above boundary conditions are both applied to the virtual boundary layers.

The crustal stress means that underground projects such as tunnels are located in a semi-infinite large space, it is difficult to simulate all strata due to limitations of calculation capacity, and thus only a core calculation region undergoes discretizing modeling by using a limited quantity of material points, and natural crustal stress environments such as gravity loads of overlying strata of the calculation model and a tectonic stress are made equivalent to the stress boundary conditions on boundaries of the calculation region.

The karst cave water pressure means that active karst caves and other bad geological structures are always encountered in the tunnel construction process, and under the comprehensive action of construction disturbance and the karst cave water pressure, surrounding rock will have seepage failure. Therefore, in order to simulate the action of the karst cave water pressure on the surrounding rock, the karst cave water pressure is made equivalent to the normal pressure of the calculation model.

The displacement constraint means that the displacement boundary condition needs to be applied to the boundaries of the calculation model in order to constrain the displacement of the calculation model and eliminate the influence of a rigid displacement.

The tunnel support means that in the tunnel construction process, lining and other manners are adopted to bear a surrounding rock stress in an excavated part of rock mass so as to control a displacement and deformation of the excavated part, and in order to truly simulate the support action in the tunnel construction process, the tunnel support is converted into the displacement boundary condition of the calculation model.
(4) A governing equation of peridynamics is converted into a motion equation in the form of an ordinary differential equation by adopting an adaptive dynamic relaxation method and setting virtual damping and virtual mass, and a speed and a displacement of the material point are iteratively solved.

A relation between a force and a displacement of any material point in the calculation model may be represented

$$λ \ddot{U} ( X , t ) + d λ \dot{U} ( X , t ) = F ( U , {U}^{′} , X , {X}^{′} ) ;$$

wherein, λ is a virtual diagonal density matrix, d is a virtual damping coefficient, X and X′ are coordinates of the material points, and U is the displacement of the material points, which are respectively represented as X^{T}={x₁, x₂, . . . , xₘ} and U^{T}={u(x₁, t), u(x₂, t), . . . , u(xₘ, t)}, wherein m represents a quantity of all the material points in the calculation region, F is a resultant force density on a material point X, and t is a time step.

The iterative solving means that a speed and a displacement of the material point at each time step are solved by using a central difference method, and a speed and a displacement at a next time step are iteratively solved in the case that a balance condition is not met. The iterative solving is represented as:

$${\dot{U}}^{n + 1 / 2} = \frac{( ( 2 - {d}^{n} Δ t ) {\dot{U}}^{n - \frac{1}{2}} + 2 Δ t {λ}^{- 1} {F}^{n} )}{( 2 + {d}^{n} Δ t )} ,$$

$${U}^{n + 1} = {U}^{n} + Δ t {\dot{U}}^{n + 1 / 2} ;$$

wherein, n is the n^{th} time of iteration, Δt is a time step length, dⁿ is a virtual damping coefficient which dynamically changes in the n^{th} time of iteration calculation process, and Fⁿ is a resultant force of the material point x in the n^{th} time of iteration calculation process.
(5) In the iterative solving process, whether the bonds of all the material points meet a failure condition or not are determined and local damage situations are recorded.

The failure condition is determination of completeness of the bonds of the material points represented by a critical stretch:

$$μ ( x , {x}^{′} , t ) = \{ \begin{matrix}1 & if s < {s}_{0} , 0 < {t}^{′} < t \\ 0 & others\end{matrix} ;$$

wherein, s₀ is a critical stretch of the bond of a given material point; s is an stretch of the bond of the material point and is represented as

$$s = \frac{\vert η + ξ \vert - \vert ξ \vert}{\vert ξ \vert} ,$$

wherein η is a relative displacement between any two material points, and ξ is relative positions between any two material points. That is, when tensile deformation s of the bond of the material points exceeds a given limiting value s₀, the bond breaks, and at the moment, the two interacting material points have no interaction relation anymore.

The local damage is defined as a ratio of a quantity of remaining complete bonds to an initial quantity of the bonds after the bonds of the material points break, and is represented as:

$$φ ( x , t ) = 1 - \frac{{\int }_{H} μ ( x , ξ , t ) {dV}_{ξ}}{{\int }_{H} {dV}_{ξ}} ;$$

wherein, V_{ξ} is a volume of the material point x. It is noted that 0≤φ≤1, where “0” represents a complete state, while “1” represents a completely damage state, and a value between “0” and “1” is a quantitative representation of a local damage degree.
(6) In the iterative solving process, a rock mass compression failure process is truly simulated by adding a short-range repulsive forces item in a basic governing equation.

The short-range repulsive forces mean that there is a problem that an infinite compression unavailability property of rock mass materials is difficult to simulate effectively because failure of the bonds is determined through a critical elongation in peridynamics. Accordingly, the short-range repulsive forces describing a compression process of any two material points is introduced into the basic motion equation of the peridynamics, namely:

$${f}_{r} ( η , ξ ) = \frac{η + ξ}{‖ η + ξ ‖} min \{ 0 , \frac{c s}{δ} ( ‖ η + ξ ‖ - {d}_{s} ) \} ;$$

wherein, dₛ=min{0.9∥x−x′|, 1.35(rₛ+rₛ′)} is a set acting range of the short-range repulsive forces, c is a micro modulus, rₛ is an equivalent radius of the material point x, and rₛ′ is an equivalent radius of a material point x′.

Further, in combination with the equivalent crustal stress and the equivalent karst cave water pressure in step (5), the basic motion equation of the peridynamics is improved to:

$$ρ \ddot{u} ( x , t ) = {\int }_{{H}_{x}} [ f ( η , ξ ) + {f}_{r} ( η , ξ ) ] d {V}_{x ′} + b ( x , t ) + {f}_{b} ( x , t ) + {f}_{p} ( x , t ) ;$$

wherein, f is an interaction force between the material points, b is a physical strength, fᵣ is a short-range repulsive force, f_{b} is an equivalent boundary stress, and fₚ is an equivalent karst cave water pressure.
(7) Whether calculation has reached a stable state or not is determined by monitoring displacement changes of the material points of the calculation model, and the tunnel construction process is simulated in the way of staged excavation and lag support by using the material point dormancy method after initial balance calculation is stable to realize simulation of the forming process of a rock mass failure water inrush channel in the tunnel construction process.

The balance condition means that by monitoring displacement change situations of the material points in the calculation model, when a displacement residual meets a certain

$$\vert \frac{{u}_{t 2} - {u}_{t 1}}{{u}_{t 1}} \vert < ϑ ,$$

it is considered that calculation has reached the stable state, where condition uₜ₁ and uₜ₂ are displacement values of a certain material point at a current time step and a previous time step respectively, and ϑ is a set critical residual value.

Initial balance means that under the condition of an initial crustal stress, the stress and the displacement of all the material points of the discretized peridynamics model reach the stable state, a stress situation and a deformation situation of strata before excavation of the underground projects are simulated, and a real in-situ stress environment where the strata are located is represented.

The material point dormancy method means that if a material point is located in an excavation region, an interaction force between the material point and any other material point in the calculation model is set to be zero, and this process is represented by introducing a scalar function ψ:

$$ψ ( x , {x}^{′} , t ) = \{ \begin{matrix}1 & if x or {x}^{′} is an active material point \\ 0 & if x or {x}^{′} is a dormant material point\end{matrix} .$$

That is, a material point in a dormant state does not produce an interaction force with any other material point in the calculation model anymore, and at the moment, a peridynamics constitutive force function is represented as:

$$f ( η , ξ ) = ψ ( x , {x}^{′} , t ) μ ( x , {x}^{′} , t ) c s .$$

The excavation region means that according to design requirements, an excavation region and boundaries thereof in underground projects such as tunnels are set in the calculation model and are represented as Hₓ′={x∈R, x∈r}, where r is a set excavation region, and when the material point x is located in the excavation region, the material point is set to be in the dormant state, otherwise being set to be in an active state.

The staged excavation and lag support means that according to design requirements, a tunnel excavation process is divided into limited steps, and a next excavation step is calculated after a previous excavation step is calculated; and support is performed after one more excavation step, which not only meets actual engineering conditions in a tunnel building process, but also meets the requirements of surrounding rock deformation and load release.

### Embodiment 2

The present embodiment provides a peridynamics method for tunnel rock mass failure water inrush catastrophe simulation, comprising the following steps:

### (1) Model Discretizing:

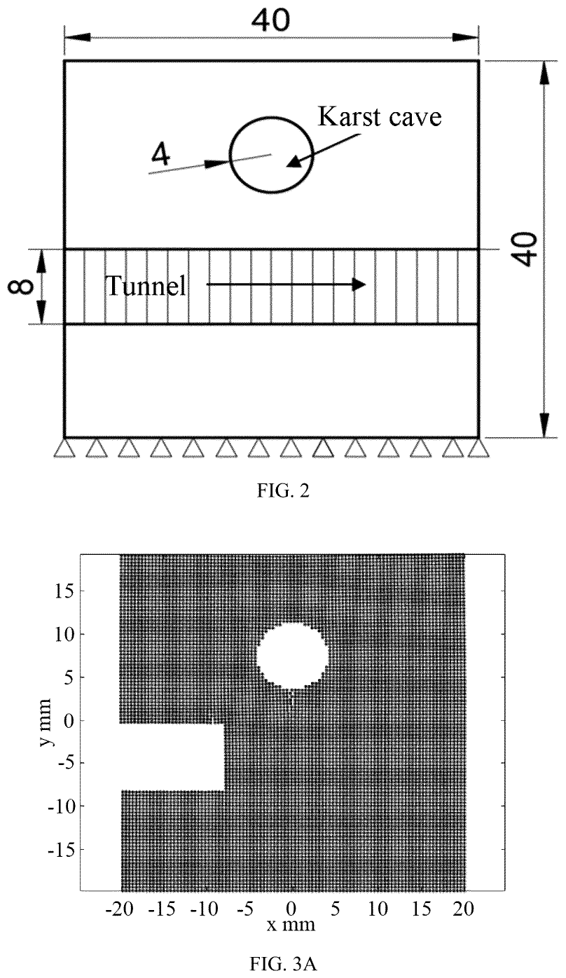

In the present embodiment, as shown in FIG. 2, a model has a length of 40 m, a width of 40 m and a thickness of 40 cm, a Young's modulus is 30 GPa, a Poisson's ratio is 0.33, a density is 2500 kg/m³, a tunnel buried depth is 600 m, a karst cave radius is 4 m, a karst cave water pressure is 4 MPa, and lateral pressure is not considered.

An upper boundary of the model receives a vertical crustal stress generated by overlying strata, and a lower boundary is a normal fixed constrained boundary. A tunnel is in the middle of the model, a height of the tunnel is about 8 m, and the tunnel is constructed through 20 excavation steps from the left to right. 100 material points are distributed in each of a length direction and a width direction in the present embodiment, one material point is disposed in a thickness direction, three material points are distributed at a virtual boundary, a distance between the material points is 40 cm, a near field range is 3.15 times the distance between the material points, and a critical elongation is set to be 0.002.

### (2) Initializing of Bonds of all Material Points:

Numbers of other material points in a given neighborhood range (∥x′−x∥≤31.5 cm) of each material point are searched and stored in a matrix, each element in scalar coefficient matrices ψ and μ is initialized to be 1, and each element in φ is initialized to be 0, that is, in an initial case, the bonds of all the material points are complete and have no local damage.

### (3) Applying of Boundary Conditions:

A vertical crustal stress generated by overlying rock mass under the gravity action is converted into an equivalent nodal force density load of a virtual boundary layers of the upper boundary, a karst cave water pressure is converted into an equivalent normal pressure on a virtual boundary layers of a karst cave, and a normal fixed constraint is applied to a virtual boundary layers of the lower boundary, that is, the model cannot have a rigid displacement in a space coordinate system.

### (4) Solving of Initial Balance State:

An adaptive dynamic relaxation algorithm is used to solve the velocity and displacement of a material point at each time step iteratively by introducing virtual mass density matrix and virtual damping coefficient, and whether a balance condition is reached or not is determined by using displacement monitoring information. In the present embodiment, a time step for initial balance calculation is 1,000 steps.

### (5) Tunnel Excavation and Support:

After initial balance is solved, coordinates of the material points in a tunnel excavation region are determined according to design requirements by using a way of staged excavation and lag support. If the material points are located in the excavation region, all bonds constants ψ of the corresponding material points are set to be 0, and at the moment, the material points in the excavation region are turned to a dormant state, while the material points outside the excavation region are still in an active state. 500 time steps are calculated for each excavation step.

Tunnel support is made equivalent to a displacement boundary condition of a calculation model to be applied to excavated surrounding rock, but support is applied after one more excavation step, so that the excavated surrounding rock obtains full deformation and stress release.

### (6) Damage Determination:

In a tunnel construction process, the material points in the surrounding rock generate a large displacement, and a cracking situation of the bond of each material point is determined through the critical elongation. If a bond stretch of the material points exceeds the critical stretch s₀, the bond constant μ of the corresponding material points is 0; if the bond stretch of the material points does not exceed the critical stretch s₀, the bond constant μ of the corresponding material points is 1; and a local damage value φ of each material point is obtained by integration.

### (7) Calculation of Short-Range Repulsive Forces:

In the tunnel construction process, the material points in the surrounding rock have compression deformation under the comprehensive action of a compression stress and the karst cave water pressure, and when bond stretch of any two material points are less than a set value, a repulsive force driving the material points to move in the opposite direction is generated. A calculation result closer to actual situations is obtained by comprehensively considering an interaction force between the material points, a physical strength, a boundary force, the karst cave water pressure and the short-range repulsive forces.

### (8) Completing of Simulation:

In the present embodiment, a tunnel is excavated through 20 excavation steps, and 500 time steps are calculated for each excavation step. Since tunnel support lags behind excavation, when calculation is completed in the present embodiment, totally 11,500 time steps need to be calculated.

### (9) Result Analysis:

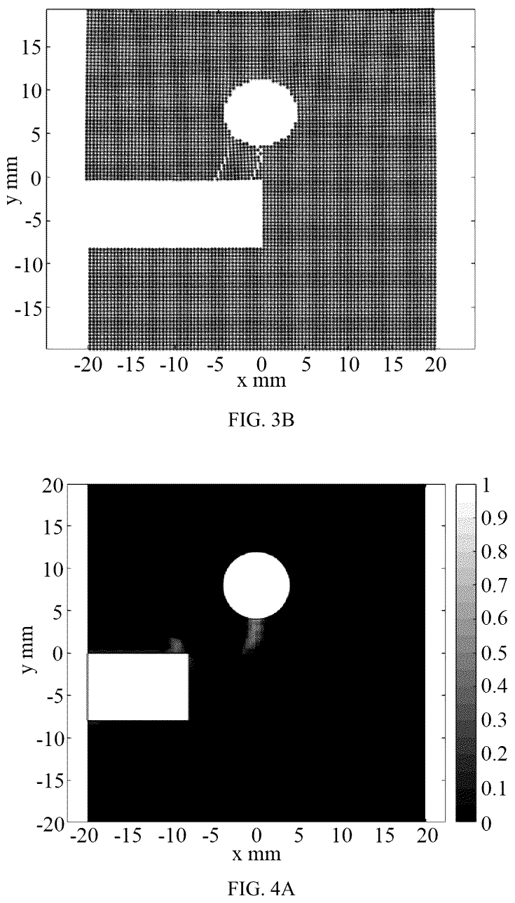

After calculation is finished, a forming process of a rock mass failure water inrush channel and a change law of surrounding rock damage and failure are obtained. As shown in FIG. 3A to FIG. 3B, the forming process of the water inrush channel in a tunnel rock mass failure water inrush catastrophe evolution process is as follows: in the tunnel construction process, under the combined action of the karst cave water pressure and excavation unloading, rock mass between the karst cave and the tunnel gradually cracks and gradually expands, extends and connects from a lower part of the karst cave and the top of the tunnel to the middle, thereby finally forming the water inrush channel.

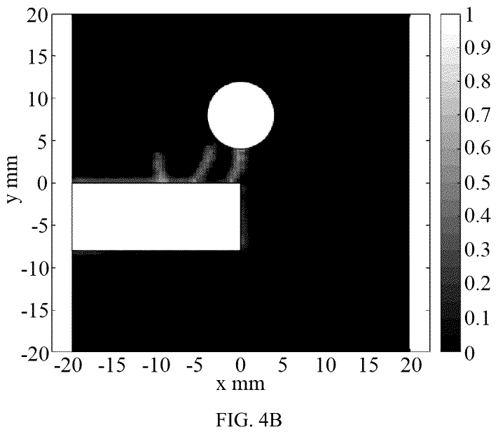

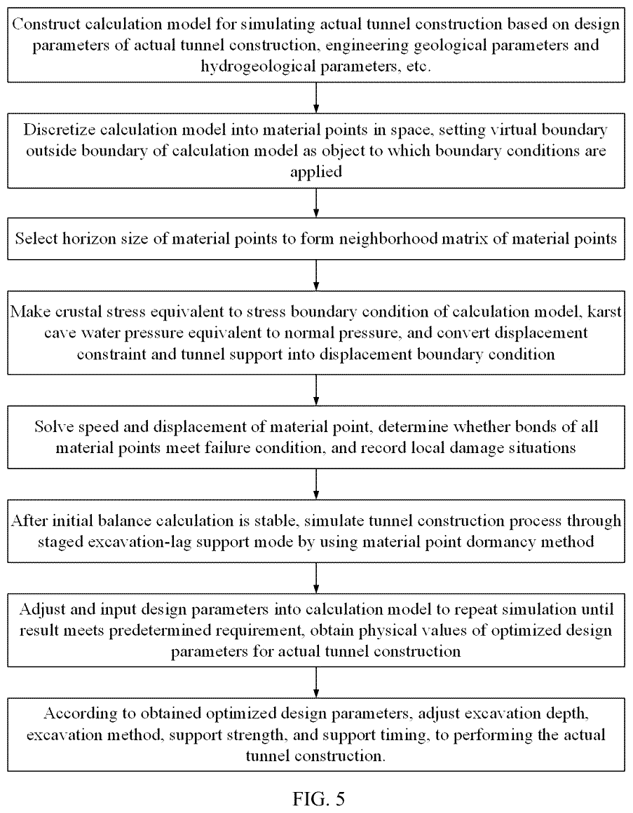

As shown in FIG. 4A to FIG. 4B, it can be seen from damage features of the surrounding rock in the tunnel rock mass failure water inrush catastrophe evolution process that tunnel excavation breaks through original crustal stress balance, resulting in gradual damage and destruction of the surrounding rock between the karst cave and the tunnel, and the damaged rock mass has a low strength, which provides an advantage path for forming the water inrush channel. Applying the simulation method of the present embodiment achieves the simulation effect closer to actual engineering.

It can be seen that the peridynamics method for tunnel rock mass failure water inrush catastrophe simulation provided by the present embodiment can effectively simulate the forming process of the rock mass failure water inrush channel and a surrounding rock damage and failure mechanism in the tunnel construction process.

### Embodiment 3

The present embodiment provides a system for tunnel rock mass failure water inrush catastrophe simulation, comprising:
a model discretizing module, configured to discretize a calculation model into material points in space, and set virtual boundary layers on an outer side of a boundary of the calculation model as an object to which boundary conditions are applied; and select a size of a horizon of the material points to form a neighborhood matrix of the material points;
a parameter equivalent model, configured to make a crustal stress on the calculation model equivalent to a stress boundary condition of the calculation model, make a karst cave water pressure equivalent to a normal pressure of the calculation model, and convert a displacement constraint and tunnel support into a displacement boundary condition;
a solving and determination model, configured to solve a speed and a displacement of the material point, determine whether bonds of all the material points meet a failure condition, and record local damage situations; and
the calculation model, configured to perform balance calculation, and simulate a tunnel construction process by using a material point dormancy method after initial balance calculation is stable.

### Embodiment 4

The present embodiment provides an electronic device, comprising a memory, a processor and a computer program stored on the memory and capable of running on the processor. The peridynamics method for tunnel rock mass failure water inrush catastrophe simulation according to Embodiment 1 is implemented when the program is executed by the processor.

### Embodiment 5

The present embodiment provides a computer readable storage medium, storing a computer program. The peridynamics method for tunnel rock mass failure water inrush catastrophe simulation according to Embodiment 1 is implemented when the program is executed by a processor.

The steps involved in Embodiments 3-5 above correspond to method Embodiment 1, and for specific implementations, refer to the relevant description part of Embodiment 1. The term “computer readable storage medium” should be understood as a single medium or multiple medium comprising one or more instruction sets; and it should also be understood to include any medium capable of storing, encoding or carrying an instruction set for execution by the processor and causing the processor to execute any method in the present invention.

### Embodiment 6

The present embodiment provides a design method for preventing and controlling water inrush catastrophe in tunnels and techniques for optimizing an actual tunnel construction, comprising the following steps:

### (1) Model Discretizing:

In the present embodiment, a calculation model for simulating an actual tunnel construction is constructed based on various parameters used in actual tunnel construction, the parameters comprise excavation parameters, support parameters, engineering geology parameters and hydrogeology parameters, etc.

Wherein, the parameters of the actual tunnel construction needed to construct the calculation model specifically comprise an excavation footage of the tunnel, a shape and size of the section, the Young's modulus of the surrounding rock, the Poisson ratio of the surrounding rock, the density of the surrounding rock, the buried depth of the tunnel, the height of the groundwater level, and the radius and water pressure of the karst cave actually detected.

An upper boundary of the model receives a vertical crustal stress generated by overlying strata, and a lower boundary is a normal fixed constrained boundary. The simulated tunnel is in a middle of the calculation model, and is constructed from the left to right through set excavation steps.

In the present embodiment, the calculation model is divided into several material points along an axis direction, a vertical direction, and a horizontal direction of the simulated tunnel and a virtual boundary in the calculation model, a distance between each adjacent material points is 40 cm, a horizon size is 3.15 times the distance between the adjacent material points, and a critical elongation is set to be 0.002.

### (2) Initializing of Bonds of all Material Points:

Numbers of other material points in a given neighborhood range (∥x′−x∥≤31.5 cm) of each material point are searched and stored in a matrix, each element in scalar coefficient matrices ψ and μ is initialized to be 1, and each element in φ is initialized to be 0, that is, in an initial case, the bonds of all the material points are complete and have no local damage.

### (3) Applying of Boundary Conditions:

A vertical crustal stress generated by overlying rock mass under the gravity action is converted into an equivalent nodal force density load of a virtual boundary layers of the upper boundary, a karst cave water pressure is converted into an equivalent normal pressure on a virtual boundary layers of a karst cave, and a normal fixed constraint is applied to a virtual boundary layers of the lower boundary, that is, the model cannot have a rigid displacement in a space coordinate system.

### (4) Solving of Initial Balance State:

An adaptive dynamic relaxation algorithm is used to solve the velocity and displacement of a material point at each time step iteratively by introducing virtual mass density matrix and virtual damping coefficient, and whether a balance condition is reached or not is determined by using displacement monitoring information. In the present embodiment, a time step for initial balance calculation is 1,000 steps.

### (5) Tunnel Excavation and Support:

After an initial balance is solved, coordinates of the material points in a tunnel excavation region are determined according to design requirements of the actual tunnel construction by using a way of staged excavation and lag support.

If the material points are located in the excavation region, all bonds constants w of the corresponding material points are set to be 0, and at the moment, the material points in the excavation region are turned to a dormant state, while the material points outside the excavation region are still in an active state. 500 time steps are calculated for each excavation step.

Tunnel support is made equivalent to a displacement boundary condition of a calculation model to be applied to excavated surrounding rock, but support is applied after one more excavation step, so that the excavated surrounding rock obtains full deformation and stress release.

### (6) Damage Determination:

Through the simulation and calculation of the construction process of the actual tunnel construction, the material points in the surrounding rock generate a large displacement, and a cracking situation of the bond of each material point is determined through the critical elongation.

If a bond stretch of the material points exceeds the critical stretch s₀, the bond constant μ of the corresponding material points is 0; if the bond stretch of the material points does not exceed the critical stretch s₀, the bond constant μ of the corresponding material points is 1; and a local damage value φ of each material point is obtained by integration.

### (7) Calculation of Short-Range Repulsive Forces:

Through the simulation and calculation of the construction process of the actual tunnel construction, the material points in the surrounding rock have compression deformation under the comprehensive action of a compression stress and the karst cave water pressure, and when bond stretch of any two material points are less than a set value, a repulsive force driving the material points to move in the opposite direction is generated.

### (8) Simulation and Optimization:

Adjusting the design parameters of the actual tunnel construction, inputting the adjusted design parameters into the calculation model, and repeat the simulation of the tunnel construction process until a simulation result meets a requirement that there will be no more water inrush catastrophe during the tunnel construction process, or the probability and/or risk level of the water inrush catastrophe will be reduced to the lowest level in a predefined risk level list, obtaining physical values of the optimized design parameters for the actual tunnel construction.

### (9) Construction Adjustment and Optimization:

According to the obtained optimized design parameters for the actual tunnel construction, adjusting an excavation depth, excavation method, support strength, and support timing of tunnel to performing the actual tunnel construction, to ensure the reliability and safety of the actual tunnel construction.

It can be seen that the design method for preventing and controlling water inrush catastrophe in the tunnels and the techniques for optimizing the actual tunnel construction provided by the present embodiment can effectively avoid the occurrence of rock mass failure and water inrush catastrophe in the actual tunnel construction, ensure the safety and reliability of the construction, reduce economic losses and avoid casualties.

The foregoing descriptions are merely preferred embodiments of the present invention, but are not intended to limit the present invention. Any modification, equivalent replacement, improvement, and the like made within the spirit and principle of the present invention shall fall within the protection scope of the present invention.

What is claimed is:

1. Techniques for optimizing an actual tunnel construction based on a design of preventing and controlling water inrush catastrophe in tunnels, to ensure the reliability and safety to the actual tunnel construction, comprising the following steps:
constructing a calculation model for simulating an actual tunnel construction based on design parameters of the actual tunnel construction, engineering geological parameters and hydrogeological parameters;
discretizing the calculation model into a series of material points having material and physical mechanics information in space, setting a virtual boundary layer of a certain thickness on an outer side of a boundary of the calculation model as an object to which boundary conditions are applied, to weaken the influence of a boundary effect on calculation results;
selecting a proper size of a horizon of the material points to form a neighborhood matrix of the material points;
making a crustal stress received by the calculation model equivalent to a stress boundary condition of the calculation model, making a karst cave water pressure equivalent to a normal pressure of the calculation model, and converting a displacement constraint and tunnel support into a displacement boundary condition;
iteratively solving a speed and a displacement of the material point by using an adaptive dynamic relaxation algorithm, determining whether bonds of all the material points meet a failure condition or not, and recording local damage situations;
in a process of the iterative solving, truly simulating a rock mass compression failure process by adding a short-range repulsion item in a basic governing equation;
after an initial balance calculation is stable, simulating a tunnel construction process through a way of staged excavation and lag support by using a material point dormancy method;
adjusting the design parameters of the actual tunnel construction, inputting the adjusted design parameters into the calculation model, and repeat the simulation of the tunnel construction process until a simulation result meets a requirement that there will be no more water inrush catastrophe during the tunnel construction process, or the probability and/or risk level of the water inrush catastrophe will be reduced to the lowest level in a predefined risk level list, obtaining physical values of the optimized design parameters for the actual tunnel construction; and
according to the obtained optimized design parameters for the actual tunnel construction, adjusting an excavation depth, excavation method, support strength, and support timing of tunnel to performing the actual tunnel construction.

2. The techniques for optimizing the actual tunnel construction according to claim 1, wherein the process of iteratively solving the speed and the displacement of the material point comprises: converting a peridynamics governing equation into a motion equation in the form of an ordinary differential equation by adopting the adaptive dynamic relaxation algorithm and setting virtual damping and virtual mass, and then iteratively solving the speed and the displacement of the material point.

3. The techniques for optimizing the actual tunnel construction according to claim 2, wherein in the iterative solving process, a rock mass compression failure process is truly simulated by adding a short-range repulsive force item in a basic governing equation; and
the speed and the displacement of the material point at each time step are solved by using a central difference method, and the speed and the displacement at a next time step are iteratively solved in the case that a balance condition is not met.

4. The techniques for optimizing the actual tunnel construction according to claim 2, wherein the peridynamics motion equation is represented as:
$$ρ \ddot{u} ( x , t ) = {\int }_{{H}_{x}} [ f ( η , ξ ) + {f}_{r} ( η , ξ ) ] d {V}_{x ′} + b ( x , t ) + {f}_{b} ( x , t ) + {f}_{p} ( x , t ) ;$$
wherein, f represents an interaction force between the material points, b represents a physical strength, fᵣ represents a short-range repulsive force, f_{b} represents an equivalent boundary stress, and fₚ represents an equivalent karst cave water pressure.

5. The techniques for optimizing the actual tunnel construction according to claim 1, wherein the failure condition is determination of completeness of the bonds of the material points represented by a critical stretch; when a bond stretch of a material point exceeds the critical stretch s₀, a bond constant of the corresponding material point μ is 0; and when a bond stretch of a material point does not exceed the critical stretch s₀, a bond constant of the corresponding material point μ is 1; and a local damage value φ of each material point is obtained by integration.

6. The techniques for optimizing the actual tunnel construction according to claim 1, wherein local damage is represented as a ratio of a quantity of remaining complete bonds to an initial quantity of bonds after the bonds of the material points break.

7. The techniques for optimizing the actual tunnel construction according to claim 1, wherein whether calculation has reached a stable state or not is determined by monitoring displacement changes of the material points of the calculation model, and after a balance condition is met, the tunnel construction process is simulated through a way of staged excavation and lag support by using the material point dormancy method:
wherein, when a displacement residual meets
$$\vert \frac{{u}_{t 2} - {u}_{t 1}}{{u}_{t 1}} \vert < ϑ ,$$
it is considered that the calculation has reached the stable state; uₜ₁ and uₜ₂ being displacement values of a certain material point at a current time step and a previous time step respectively, and ϑ being a set critical residual value.
